(19) United States
(12) Patent Application Publication
(10) Pub. No.: US 2025/0289658 A1
(43) Pub. Date: Sep. 18, 2025

(54) Transport Vehicle

(71) Applicant: Daifuku Co., Ltd., Osaka-shi (JP)

(72) Inventor: Daichi Tomida, Hinocho (JP)

(21) Appl. No.: 19/077,115

(22) Filed: Mar. 12, 2025

(30) Foreign Application Priority Data
Mar. 14, 2024 (JP) 2024-040115

(51) Int. Cl. B65G 1/04

(52) U.S. Cl. CPC B65G 1/0464

(57) ABSTRACT

A transport vehicle includes a holding device and a restrictor. The holding device includes a pair of holders and a holder drive. A first holder includes a first extension and a first support. A second holder includes a second extension and a second support. The restrictor includes a first restrictor assembly and a second restrictor assembly. The first restrictor assembly is switchable between a first restrictive position to restrict movement of the first holder and a first unrestrictive position. The second restrictor assembly is switchable between a second restrictive position to restrict movement of the second holder and a second unrestrictive position.

### CROSS-REFERENCE TO RELATED APPLICATION

This application claims priority to Japanese Patent Application No. 2024-040115 filed Mar. 14, 2024, the disclosure of which is hereby incorporated by reference in its entirety.

### BACKGROUND OF THE INVENTION

### Field of the Invention

The present invention relates to a transport vehicle that transports an article.

### Description of Related Art

For example, Japanese Unexamined Patent Application Publication No. 2009-040563 (JP 2009-040563) describes a technique for a transport vehicle. Reference signs in parentheses used hereafter in describing the background are the reference signs in JP 2009-040563.

A transport vehicle (transport device 5) described in JP 2009-040563 includes a holding device (gripper assembly 2) for holding an article (front opening unified pod or FOUP 1), a pair of pressers (51), and an extendable assembly (100a). The holding device includes a pair of grippers (15). The pair of grippers (15) grip a flange (finger 16) at the top of the article. The article is thus hung from the holding device. The pair of pressers (51) are arranged to clamp the article held by the holding device. This transport vehicle reduces vibrations of the article caused by the traveling transport vehicle by clamping the article held by the holding device with the pair of pressers (51) during the travel. The extendable assembly (100a) overlaps the article when viewed vertically at a position below the article held by the holding device during travel of the transport vehicle. The article can thus avoid falling off the holding device.

In the transport vehicle described in JP 2009-040563, an article is hung from above, or in other words, supported from above during transportation. When, for example, an article with no flange is to be transported, the transport vehicle may support the article at the bottom. The article supported at the bottom by the transport vehicle can also vibrate relatively largely or fall off the transport vehicle during transportation in response to vibrations of or an inertial force of some magnitude acting on the transport vehicle.

### SUMMARY OF THE INVENTION

Techniques are thus awaited for appropriately holding an article during transportation with a transport vehicle that includes a holding device for holding and releasing an article and a restrictor that restricts the article held by the holding device from falling.

A transport vehicle according to an aspect of the disclosure is a transport vehicle for transporting an article. The transport vehicle includes a holding device that holds and releases the article, and a restrictor that restricts the article held by the holding device from falling. The holding device includes a pair of holders that hold the article, and a holder drive that switches the pair of holders between a holding position at which the pair of holders are closer to each other to hold the article and a releasing position at which the pair of holders are away from each other to release the article. The pair of holders include a first holder on a first side in a holding direction in which the pair of holders move closer to and away from each other, and a second holder on a second side in the holding direction. The second side is opposite to the first side. The first holder includes a first extension disposed on the first side relative to the article in the holding direction and extending vertically, and a first support protruding from the first extension toward the second side in the holding direction to support a bottom of the article from below. The second holder includes a second extension disposed on the second side relative to the article in the holding direction and extending vertically, and a second support protruding from the second extension toward the first side in the holding direction to support the bottom of the article from below. The restrictor includes a first restrictor assembly and a second restrictor assembly. The first restrictor assembly is switchable between a first restrictive position and a first unrestrictive position. The first restrictive position is a position to restrict movement of the first holder toward the first side in the holding direction with the first holder and the second holder at the holding position. The first unrestrictive position is a position to remove restriction on the first holder. The second restrictor assembly is switchable between a second restrictive position and a second unrestrictive position. The second restrictive position is a position to restrict movement of the second holder toward the second side in the holding direction with the first holder and the second holder at the holding position. The second unrestrictive position is a position to remove restriction on the second holder.

This structure includes the first restrictor assembly that restricts movement of the first holder toward the first side in the holding direction and the second restrictor assembly that restricts movement of the second holder toward the second side in the holding direction. The structure can thus restrict the distance between the first support and the second support from increasing in the holding direction due to, for example, warping or rattling of the holders, thus restricting the article from falling off the pair of holders.

The structure restricts movement of each of the pair of holders with the first restrictor assembly at the first restrictive position and the second restrictor assembly at the second restrictive position, thus easily reducing vibrations of the article being transported by the transport vehicle.

The structure also allows the pair of holders to easily move in the holding direction and switch between the holding position and the releasing position by switching the first restrictor assembly to the first unrestrictive position and the second restrictor assembly to the second unrestrictive position. Thus, the pair of holders can appropriately hold and release the article.

As described above, the structure can appropriately hold the article during transportation.

Further aspects and advantages of the transport vehicle will be apparent from exemplary and nonlimiting embodiments described below with reference to the drawings.

### BRIEF DESCRIPTION OF THE DRAWINGS

FIG. 1 is a schematic diagram of a transport facility.

FIG. 2 is a side view of a transport vehicle.

FIG. 3 is a schematic side view of a holding device transferring an article.

FIG. 4 is a schematic side view of a first restrictor assembly at a first unrestrictive position.

FIG. 5 is a schematic side view of the first restrictor assembly at a first restrictive position.

FIG. 6 is a schematic plan view of a restrictor at the first unrestrictive position and a second unrestrictive position.

FIG. 7 is a schematic plan view of the restrictor at the first restrictive position and a second restrictive position.

FIG. 8 is a control block diagram.

FIG. 9 is a control flowchart.

### DESCRIPTION OF THE INVENTION

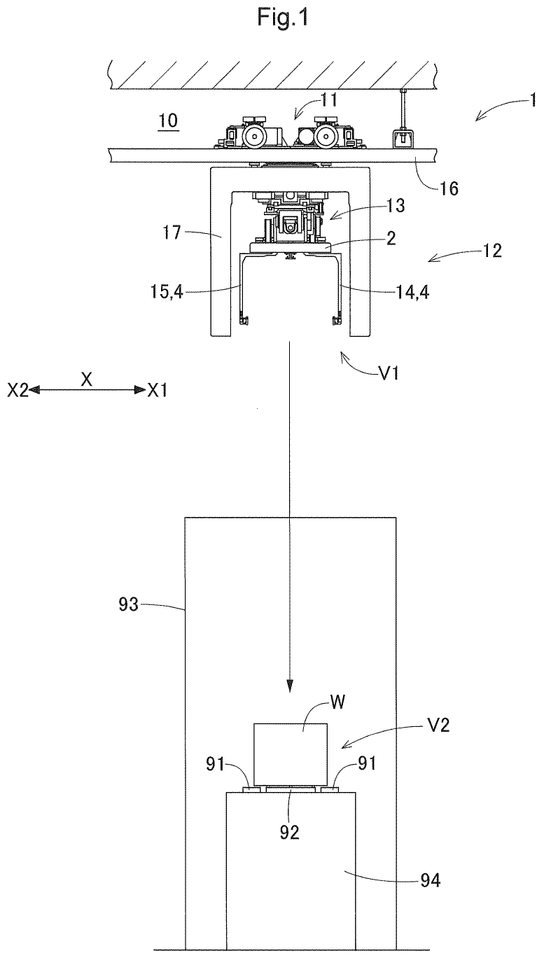

A transport vehicle according to one or more embodiments used in a transport facility 10 will be described with reference to the drawings. As shown in FIG. 1, the transport facility 10 includes a transport vehicle 1 and a processing device 93 that processes an article W. The transport vehicle 1 transports the article W. The transport vehicle 1 travels along a travel path to transport the article W to and from a transfer area 92. The transfer area 92 is disposed on, for example, a storage shelf (not shown) for storing articles W or on an article mount 94 on the processing device 93.

In this example, the transport facility 10 includes multiple processing devices 93, one of which is shown in the example in FIG. 1. The transport vehicle 1 (each of multiple transport vehicles 1 in this example) transports the article W between multiple processing devices 93. The article mount 94 supports the article W transferred from the transport vehicle 1. The article mount 94 also supports the article W unloaded from an internal space of the processing device 93. The transport vehicle 1 stops at a position corresponding to the transfer area 92 (a position directly above the article mount 94) on the travel path to transfer the article W to and from the article mount 94. In this example, the article W is a container. In this example, the article W is, but not limited to, a container (front opening shipping box, or FOSB) containing semiconductor substrates. The article W may be, for example, a front opening unified pod (FOUP) or a reticle container (reticle pod) that contains reticles. The processing device 93 processes semiconductor substrates stored in the article W (container), but may process, for example, the article W. Although the article mount 94 includes a transport device that transports the article W between the internal space of the processing device 93 and the transfer area 92, the transport device is not to be described. The article W may be other than a container, and may be, for example, a product or a machine part.

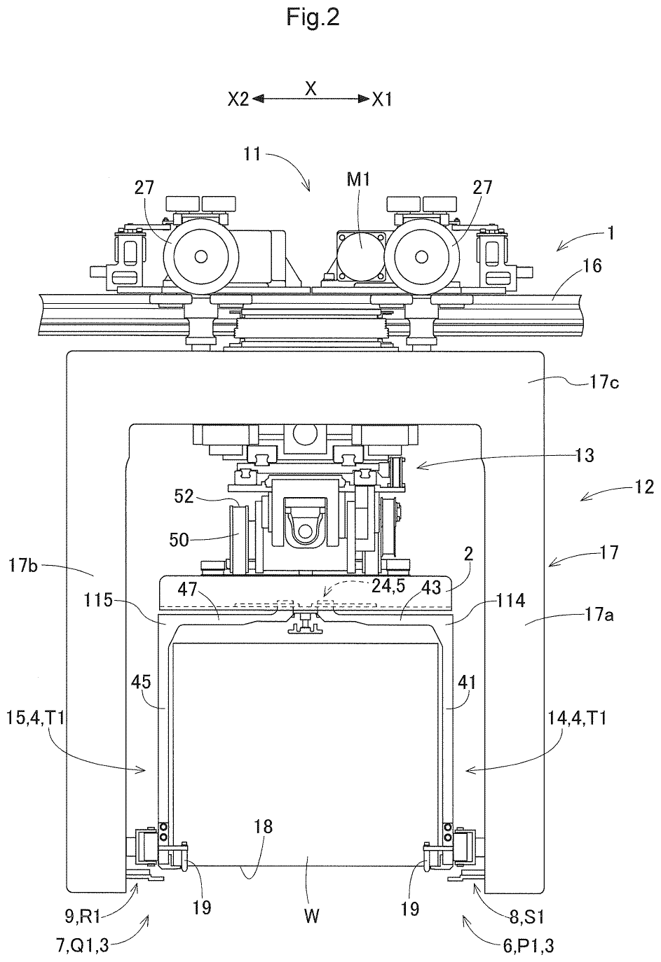

As shown in FIGS. 1 and 2, the travel path for the transport vehicle 1 extends along the ceiling. In this example, rails 16 extend along the travel path. The transport vehicle 1 travels as being guided along the rails 16 (a pair of rails 16 in this example) hung from the ceiling. The transport vehicle 1 is thus, but not limited to, a ceiling-hung transport vehicle.

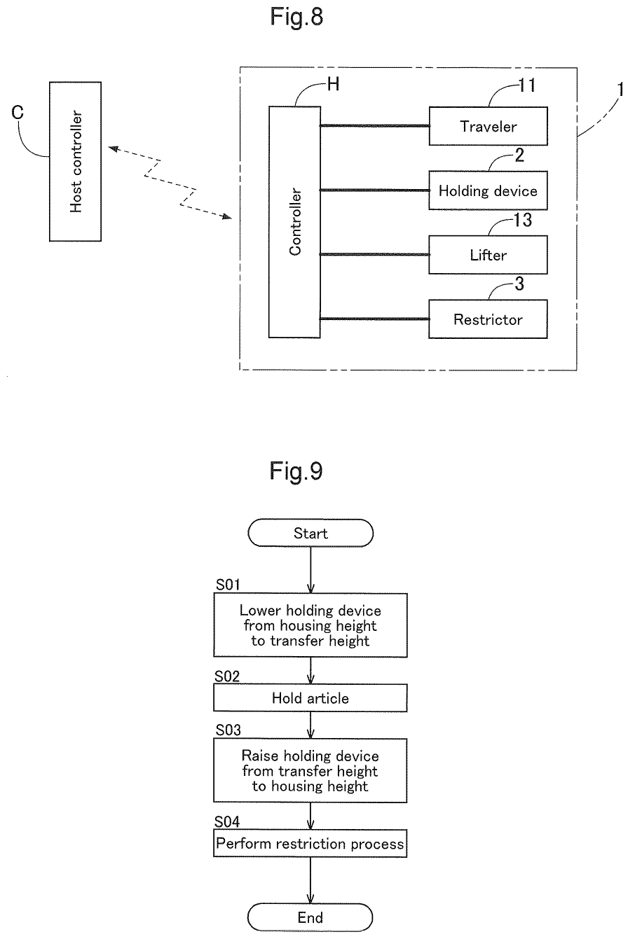

As shown in FIG. 2, the transport vehicle 1 includes a holding device 2 that holds and releases the article W and a restrictor 3 that restricts the article W held by the holding device 2 from falling. In the present embodiment, the transport vehicle 1 further includes a traveler 11 that travels, a housing 12 supported by the traveler 11 and houses the holding device 2 and the article W held by the holding device 2 during travel of the traveler 11, and a lifter 13 that raises and lowers the holding device 2 to place the holding device 2 into and out of the housing 12. The transport vehicle 1 also includes a controller H (FIG. 8) that controls the traveler 11, the holding device 2, the lifter 13, and the restrictor 3. A direction in which the transport vehicle 1 transporting the article W travels is hereafter referred to as a holding direction X, and a direction perpendicular to the holding direction X when viewed vertically is hereafter referred to as a width direction Y. One side in the holding direction X is referred to as a first side X1 in the holding direction, and the other side in the holding direction X is referred to as a second side X2 in the holding direction.

As shown in FIG. 2, the traveler 11 includes wheels 27 that roll on the rails 16 and a travel motor M1. In this example, the travel motor M1 drives at least one of the wheels 27 and provides a propelling force for the transport vehicle 1 guided along the pair of rails 16 to move.

The housing 12, the holding device 2, and the lifter 13 are supported by the traveler 11 below the traveler 11, with the rails 16 between the traveler 11 and each of the housing 12, the holding device 2, and the lifter 13.

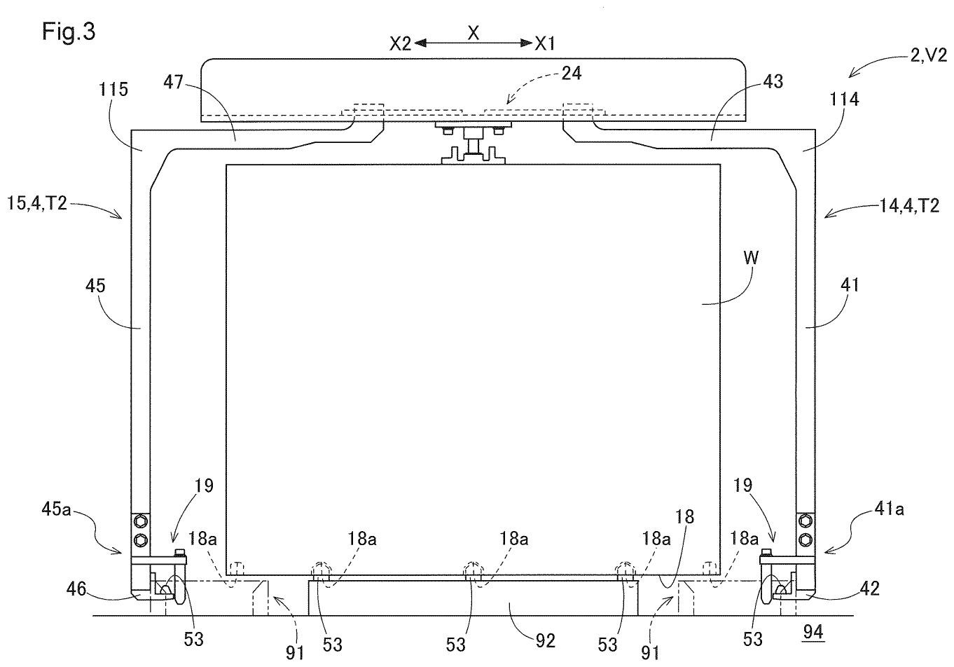

As shown in FIGS. 1 and 3, the lifter 13 raises and lowers the holding device 2 and the article W held by the holding device 2 between a housing height V1 and a transfer height V2 that is lower than the housing height V1. When the transport vehicle 1 travels, the lifter 13 raises the article W held by the holding device 2 from the transfer height V2 to the housing height V1. When the article W is transferred from the transport vehicle 1 to the transfer area 92 on the article mount 94, the lifter 13 lowers the article W held by the holding device 2 from the housing height V1 to the transfer height V2. At the housing height V1, the article W and the holding device 2 are housed in the housing 12. At the transfer height V2, the article W is placed on the transfer area 92.

As shown in FIG. 2, the lifter 13 includes a winder 50, a belt 52 wound around the winder 50 and connected to the holding device 2 at its distal end, and a lift motor (not shown) that rotates the winder 50 to drive the belt 52. The lifter 13 winds and unwinds the belt 52 by driving the lift motor to rotate the winder 50. The lifter 13 thus raises and lowers the holding device 2 and the article W held by the holding device 2 relative to the housing 12.

In this example, when the holding device 2 is at the housing height V1, the entire lifter 13 is housed in the housing 12. The winder 50 and the lift motor are inside the housing 12, independently of the vertical position of the holding device 2.

As shown in FIGS. 1 and 2, the housing 12 includes a cover 17. At the housing height V1, the holding device 2 and the article W held by the holding device 2 are housed in a space surrounded by the cover 17. The cover 17 covers the holding device 2 and the article W held by the holding device 2 at the housing height V1 from both sides in the holding direction X and from above. The cover 17 includes a first cover 17a, a second cover 17b disposed on the second side X2 relative to the first cover 17a in the holding direction with the article W between the first cover 17a and the second cover 17b, and a connecting portion 17c connecting the first cover 17a and the second cover 17b. The connecting portion 17c connects the upper end of the first cover 17a and the upper end of the second cover 17b. The connecting portion 17c is supported by the traveler 11 with a connecting shaft. The connecting portion 17c extends in the holding direction X. The first cover 17a and the second cover 17b extend in the vertical direction. Various devices such as an obstacle sensor may be placeable inside the cover 17.

As shown in FIGS. 1 to 3, the holding device 2 includes a pair of holders 4 that hold an article W and a holder drive 5. The holder drive 5 switches the pair of holders 4 between a holding position T1 (FIG. 2) at which the pair of holders 4 are closer to each other to hold the article W and a releasing position T2 (FIG. 3) at which the pair of holders 4 are away from each other to release the article W. The holding device 2 further includes engagement portions 19 that position the holding device 2 at the transfer height V2. The holding direction X is a direction in which the pair of holders 4 move closer to or away from each other. In the present embodiment, as described above, the holding direction X is the same direction as the direction in which the transport vehicle 1 travels. The pair of holders 4 include a first holder 14 on the first side X1 in the holding direction and a second holder 15 on the second side X2 in the holding direction. In the present embodiment, the first holder 14 and the second holder 15 support the article W from below. The holder drive 5 switches the positioning of the pair of holders 4 (the first holder 14 and the second holder 15) by moving the pair of holders 4 in the holding direction X.

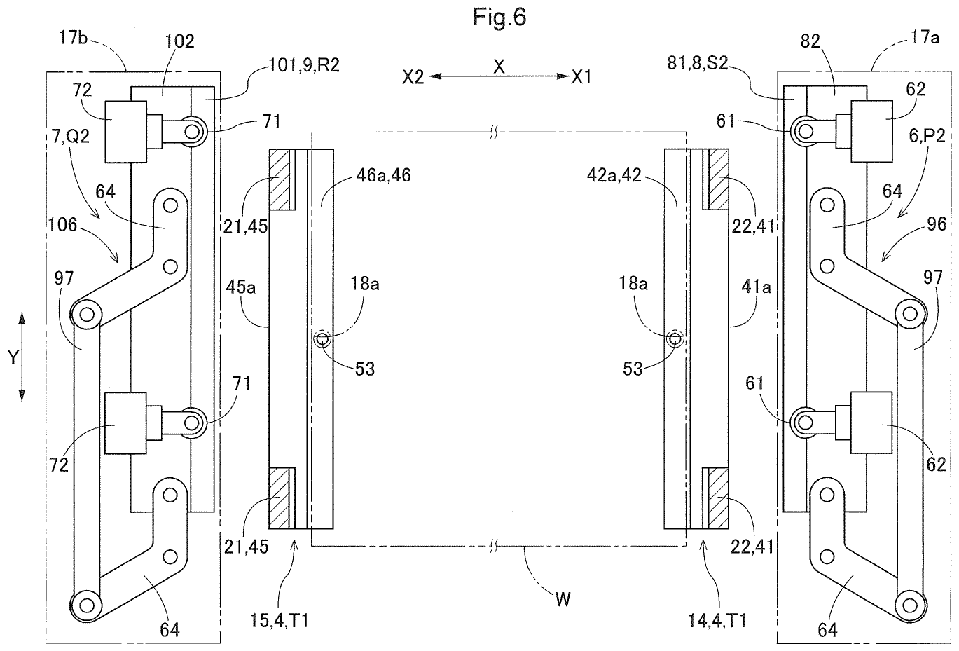

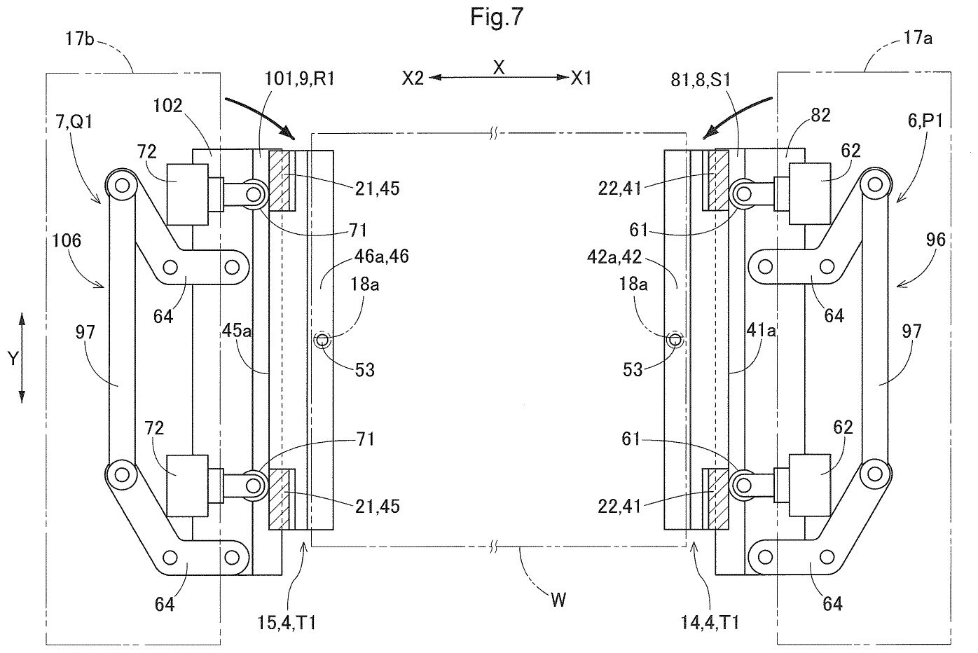

As shown in FIGS. 2 and 3, the first holder 14 includes a first extension 41 disposed on the first side X1 relative to the article W in the holding direction and extends vertically, and a first support 42 protruding from the first extension 41 toward the second side X2 in the holding direction to support a bottom 18 of the article W from below. The first holder 14 further includes a first connector 43 connecting the first extension 41 to the holder drive 5. The first support 42 protrudes from the lower end of the first extension 41 toward the second side X2 in the holding direction (toward the article W when viewed vertically). In this example, the first connector 43 is disposed above the article W being held. The first connector 43 extends in the holding direction X and has the end on the second side X2 in the holding direction connected to a guide assembly 24 (described later). The first extension 41 extends downward from the end of the first connector 43 on the first side X1 in the holding direction. In the example in FIGS. 6 and 7, the first extension 41 includes multiple (two in this example) first posts 22 at separate positions in the width direction Y. The first posts 22 extend in the vertical direction and connect the first connector 43 and the first support 42. The first support 42 includes a first support plate 42a that supports the bottom 18 of the article W from below at the holding position T1. The first support plate 42a is fixed to the first extension 41 (the first posts 22 in this example) and protrudes inward in the holding direction X (toward the second side X2 in the holding direction) from the first extension 41 when viewed vertically. The first support plate 42a is elongated in the width direction Y. The first support plate 42a includes an engagement pin 53 (FIG. 6) protruding upward.

As shown in FIGS. 2 and 3, the second holder 15 includes a second extension 45 disposed on the second side X2 relative to the article W in the holding direction and extends vertically, and a second support 46 protruding from the second extension 45 toward the first side X1 in the holding direction to support the bottom 18 of the article W from below. The second holder 15 further includes a second connector 47 connecting the second extension 45 and the holder drive 5. In the present embodiment, the second holder 15 has the same structure as the first holder 14. Thus, the structure of the second holder 15 will be described briefly in part. The second support 46 protrudes from the lower end of the second extension 45 toward the first side X1 in the holding direction. In this example, the second connector 47 is disposed above the article W being held. The second connector 47 has the end on the first side X1 in the holding direction connected to the guide assembly 24 (described later). The second extension 45 extends downward from the end of the second connector 47 on the second side X2 in the holding direction. In the example in FIGS. 6 and 7, the second extension 45 includes multiple (two in this example) second posts 21 at separate positions in the width direction Y. The second posts 21 extend in the vertical direction and connect the second connector 47 and the second support 46. The second support 46 includes a second support plate 46a that supports the bottom 18 of the article W from below at the holding position T1. The second support plate 46a is fixed to the second extension 45 (the second posts 21 in this example) and protrudes inward in the holding direction X (toward the first side X1 in the holding direction) from the second extension 45 when viewed vertically. The second support plate 46a includes an engagement pin 53 protruding upward.

As shown in FIGS. 2 and 3, the holder drive 5 is above the article W held by the pair of holders 4. The holder drive 5 applies a driving force to a first upper portion 114 that is a portion in the first extension 41 and above the article W and to a second upper portion 115 that is a portion in the second extension 45 and above the article W. In this example, the first upper portion 114 is the upper end of the first extension 41. Similarly, the second upper portion 115 is the upper end of the second extension 45. The end of the first connector 43 on the first side X1 in the holding direction is connected to the first upper portion 114. The end of the second connector 47 on the second side X2 in the holding direction is connected to the second upper portion 115. The holder drive 5 includes the guide assembly 24 and a drive motor (not shown). The guide assembly 24 (a linear guide in this example) guides the first connector 43 and the second connector 47 to move in the holding direction X. The first connector 43 and the second connector 47 are connected to the drive motor with ball screws. In this structure, the driving force generated by the drive motor is transmitted to each of the first upper portion 114 and the second upper portion 115 through the ball screws, the first connector 43, and the second connector 47. This moves the pair of holders 4 closer to and away from each other in the holding direction X, switching them between the holding position T1 and the releasing position T2.

When the pair of holders 4 are at the holding position T1, the article W is supported from below by the first support plate 42a and the second support plate 46a. In this example, the article W has multiple engagement holes 18a in the bottom 18. When the article W is supported by the first support plate 42a and the second support plate 46a, the engagement hole 18a adjacent to the end of the bottom 18 on the first side X1 in the holding direction engages with the engagement pin 53 on the first support plate 42a, and the engagement hole 18a adjacent to the end of the bottom 18 on the second side X2 in the holding direction engages with the engagement pin 53 on the second support plate 46a. In this example, the bottom 18 includes, along its two ends in the holding direction X, rail portions (upward-recessed portions extending in the width direction Y) to come in contact and fit with the first support plate 42a and the second support plate 46a. Each rail portion has the engagement hole 18a. The bottom 18 also has other engagement holes 18a engageable with engagement pins 53 on the transfer area 92 (FIG. 3). In the present embodiment, the pair of holders 4 support the article W on the bottom surface of the bottom 18, but the structure is not limited to this.

In this example, as shown in FIGS. 2 and 3, the engagement portions 19 are each attached to a surface of the corresponding one of the first holder 14 and the second holder 15. The surface faces one side in the width direction Y. In this example, the lower end of the first extension 41 and the lower end of the second extension 45 are fixed to the respective engagement portions 19. Each engagement portion 19 is a rod elongated in the vertical direction, with its lower end disposed below the first support plate 42a or the second support plate 46a.

To transfer the article W from the transport vehicle 1 to the transfer area 92, the lifter 13 lowers the holding device 2 and the article W from the housing height V1 to the transfer height V2. In this example, the article mount 94 includes the transfer area 92 as a mount on which the article W is placeable. The article mount 94 also includes guides 91 adjacent to the transfer area 92. Each guide 91 is a grooved member that is open upward and extends in the holding direction X. At the transfer height V2, the engagement portions 19 engage with the guides 91 from above. At the transfer height V2, the article W is placed on the transfer area 92, and the engagement holes 18a in the bottom 18 engage with the corresponding engagement pins 53 on the transfer area 92. When the first support plate 42a and the second support plate 46a are lowered to a position below the bottom 18, the article W is released from the first support plate 42a and the second support plate 46a. The pair of holders 4 then move away from each other to the releasing position T2. In this state, the engagement portions 19 move in the holding direction X as being guided by the guides 91. To transfer the article W from the transfer area 92 to the transport vehicle 1, the above operations are performed in the reversed order. In the illustrated example, the guides 91 as a pair correspond to the engagement portions 19 as a pair. The guides 91 guide the engagement portions 19 to appropriately position the holding device 2 relative to the transfer area 92, thus achieving appropriate transfer of the article W. Such a transfer operation is controlled by the controller H.

As shown in FIG. 2 and FIGS. 4 to 7, the restrictor 3 includes a first restrictor assembly 6 and a second restrictor assembly 7. The first restrictor assembly 6 and the second restrictor assembly 7 are disposed in the housing 12. More specifically, the first restrictor assembly 6 and the second restrictor assembly 7 are disposed in the cover 17. The first restrictor assembly 6 and the second restrictor assembly 7 are disposed outward from the pair of holders 4 in the holding direction X. In the present embodiment, the restrictor 3 further includes a first support assembly 8 and a second support assembly 9.

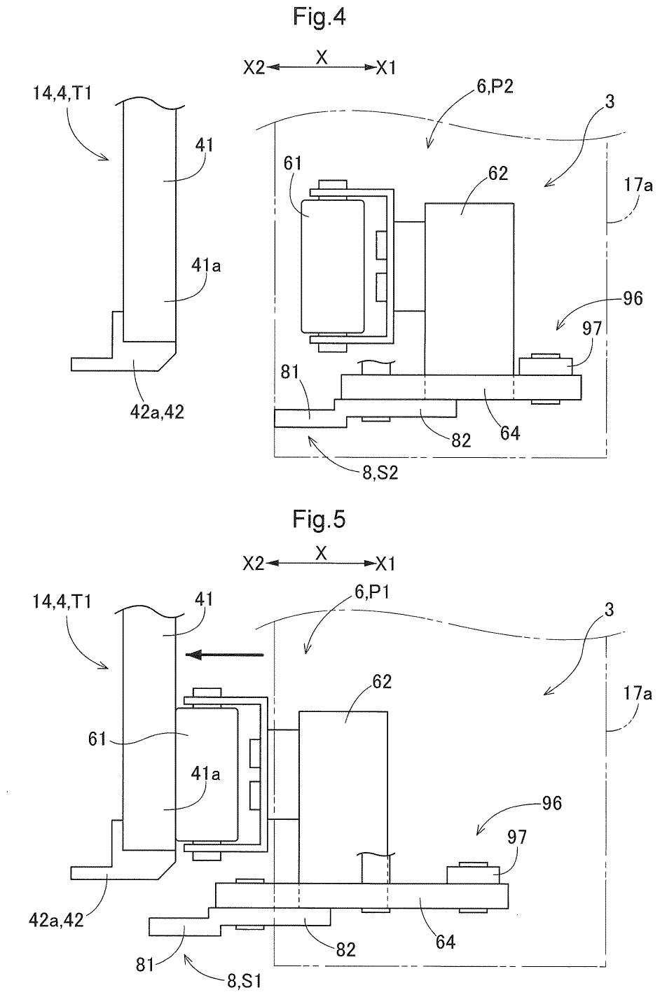

As shown in FIGS. 4 to 7, the first restrictor assembly 6 switches between a first restrictive position P1 and a first unrestrictive position P2. At the first restrictive position P1, the first restrictor assembly 6 restricts movement of the first holder 14 toward the first side X1 in the holding direction with the first holder 14 and the second holder 15 at the holding position T1. At the first unrestrictive position P2, the first restrictor assembly 6 removes restriction on movement of the first holder 14. In the present embodiment, the first restrictor assembly 6 switches its positioning independently of switching in the positioning of the first holder 14 and the second holder 15. More specifically, the first restrictor assembly 6 switches between the first restrictive position P1 and the first unrestrictive position P2 with the first holder 14 and the second holder 15 at the holding position T1.

In the present embodiment, the first restrictor assembly 6 at the first restrictive position P1 presses the first holder 14 from outside in the holding direction X (from the first side X1 in the holding direction). The first restrictor assembly 6 thus restricts movement of the first holder 14 toward the first side X1 in the holding direction. The first restrictor assembly 6 is disposed not to press the holder drive 5. In this example, the first restrictor assembly 6 is disposed in the first cover 17a. More specifically, the first restrictor assembly 6 is disposed at the lower end of the first cover 17a. Pressing herein includes simply being in contact under a pressing force of any magnitude.

In the present embodiment, the first restrictor assembly 6 at the first restrictive position P1 presses either a portion in the first extension 41 and below the first upper portion 114 or the first support 42. In this example, as shown in FIGS. 2 and 5, the first restrictor assembly 6 at the first restrictive position P1 presses the portion in the first extension 41 and below the first upper portion 114, or more specifically, a lower end portion in the first extension 41 (a first lower end portion 41a) that overlaps the article W as viewed in the holding direction X. In the illustrated example, the first restrictor assembly 6 presses a portion in the first extension 41 and immediately above the first support 42. In this example, the first restrictor assembly 6 includes first pressing members 61, first supporters 62 supporting the first pressing members 61, and a first mover 96. At the first restrictive position P1, the first pressing members 61 protrude relative to the first cover 17a toward the second side X2 in the holding direction while being in contact with a surface of the article W held by the holding device 2 facing the first side X1 in the holding direction. At the first unrestrictive position P2, the first pressing members 61 are inside the first cover 17a, thus being away from the article W held by the holding device 2 in the holding direction X. The first mover 96 moves the first pressing members 61 in the holding direction X to switch the first pressing members 61 between the first restrictive position P1 and the first unrestrictive position P2.

As shown in FIGS. 6 and 7, the second restrictor assembly 7 switches between a second restrictive position Q1 and a second unrestrictive position Q2. At the second restrictive position Q1, the second restrictor assembly 7 restricts movement of the second holder 15 toward the second side X2 in the holding direction with the first holder 14 and the second holder 15 at the holding position T1. At the second unrestrictive position Q2, the second restrictor assembly 7 removes restriction on movement of the second holder 15. In the present embodiment, the second restrictor assembly 7 switches its positioning independently of switching in the positioning of the first holder 14 and the second holder 15. More specifically, the second restrictor assembly 7 switches between the second restrictive position Q1 and the second unrestrictive position Q2 with the first holder 14 and the second holder 15 at the holding position T1.

In the present embodiment, the second restrictor assembly 7 at the second restrictive position Q1 presses the second holder 15 from outside in the holding direction X (from the second side X2 in the holding direction). The second restrictor assembly 7 thus restricts movement of the second holder 15 toward the second side X2 in the holding direction. The second restrictor assembly 7 is disposed not to press the holder drive 5. In this example, the second restrictor assembly 7 is disposed in the second cover 17b. More specifically, the second restrictor assembly 7 is disposed at the lower end of the second cover 17b.

At the second restrictive position Q1, the second restrictor assembly 7 presses either a portion in the second extension 45 and below the second upper portion 115 or the second support 46. In this example, as shown in FIG. 2, the second restrictor assembly 7 at the second restrictive position Q1 presses the portion in the second extension 45 and below the second upper portion 115, or more specifically, a lower end portion in the second extension 45 (a second lower end portion 45a) that overlaps the article W as viewed in the holding direction X. In the illustrated example, the second restrictor assembly 7 presses a portion in the second extension 45 and immediately above the second support 46. In this example, the second restrictor assembly 7 includes second pressing members 71, second supporters 72 supporting the second pressing members 71, and a second mover 106. At the second restrictive position Q1, the second pressing members 71 protrude relative to the second cover 17b toward the first side X1 in the holding direction while being in contact with a surface of the article W held by the holding device 2 facing the second side X2 in the holding direction. At the second unrestrictive position Q2, the second pressing members 71 are inside the second cover 17b, thus being away from the article W held by the holding device 2 in the holding direction X. The second mover 106 moves the second pressing members 71 in the holding direction X to switch the second pressing members 71 between the second restrictive position Q1 and the second unrestrictive position Q2.

In the present embodiment, as described above, the second restrictor assembly 7 presses the second holder 15 at the same vertical position as the first restrictor assembly 6, but the structure is not limited to this. For example, the second restrictor assembly 7 may press the second holder 15 at a position higher than or lower than the first restrictor assembly 6. The vertical position at which the first restrictor assembly 6 presses the first holder 14 (the first extension 41 in this example) may also be changed as appropriate.

As shown in FIGS. 4 to 7, in response to the first restrictor assembly 6 at the first restrictive position P1, the first support assembly 8 is at a first overlapping position S1 below the first holder 14 at which the first support assembly 8 overlaps the first holder 14 when viewed vertically. In response to the first restrictor assembly 6 at the first unrestrictive position P2, the first support assembly 8 is at a first non-overlapping position S2 at which the first support assembly 8 avoids overlapping the first holder 14 when viewed vertically. In this example, the first support assembly 8 is movable in the holding direction X between the first overlapping position S1 and the first non-overlapping position S2. The first support assembly 8 includes a first overlapping portion 81 that overlaps the first holder 14 at the first overlapping position S1 when viewed vertically, a first base 82 supporting the first overlapping portion 81, and a first mover 96 that moves the first overlapping portion 81 and the first base 82 in the holding direction X. In other words, in this example, the first mover 96 is shared by both the first restrictor assembly 6 and the first support assembly 8. The first overlapping portion 81 is adjacent to the first base 82 on the second side X2 in the holding direction. In the illustrated example, the first overlapping portion 81 is continuous with the first base 82. The first overlapping portion 81 and the first base 82 are each in the form of a plate elongated in the width direction Y. In this example, the first overlapping portion 81 and the first base 82 are moved integrally by the first mover 96 in the holding direction X. At the first overlapping position S1, the first overlapping portion 81 and the first base 82 protrude inward in the holding direction X (toward the second side X2 in the holding direction) relative to the first cover 17a. At the first non-overlapping position S2, the first overlapping portion 81 and the first base 82 are on the first side X1 relative to the first overlapping position S1 in the holding direction, entirely housed inside the first cover 17a. At the first non-overlapping position S2, the first overlapping portion 81 at a position not overlapping the first holder 14 when viewed vertically may or may not be housed in the first cover 17a. In the example in FIGS. 5 and 7, the first overlapping portion 81 at the first overlapping position S1 is below the first support 42 and overlaps at least a part of the first support 42 when viewed vertically. More specifically, at the first overlapping position S1, the first overlapping portion 81 overlaps a portion of the first support 42 disposed on the first side X1 in the holding direction relative to the first support plate 42a when viewed vertically, without overlapping the first support plate 42a on which the article W is placed. At the first overlapping position S1, the first overlapping portion 81 may overlap, for example, the entire first support 42 or overlap the first support plate 42a alone when viewed vertically.

In this example, the first mover 96 is disposed in the first cover 17a. The first mover 96 includes a link 97 and an advancement-retraction motor (not shown). In the illustrated example, the first base 82 is supported from above by link members 64 included in the link 97. The link 97 transmits a driving force from the advancement-retraction motor to the first base 82. As described above, the first pressing members 61 are supported by the first base 82 with the first supporters 62. As described above, the first overlapping portion 81 is continuous with the first base 82. Thus, the first pressing members 61 and the first overlapping portion 81 move integrally in the holding direction X, or in other words, advance and retract relative to the first cover 17a, as driven by the first mover 96. In the illustrated example, multiple (two in this example) first pressing members 61 are at separate positions in the width direction Y.

As shown in FIGS. 6 and 7, in response to the second restrictor assembly 7 at the second restrictive position Q1, the second support assembly 9 is at a second overlapping position R1 below the second holder 15 at which the second support assembly 9 overlaps the second holder 15 when viewed vertically. In response to the second restrictor assembly 7 at the second unrestrictive position Q2, the second support assembly 9 is at a second non-overlapping position R2 at which the second support assembly 9 avoids overlapping the second holder 15 when viewed vertically. In this example, the second support assembly 9 is movable in the holding direction X between the second overlapping position R1 and the second non-overlapping position R2. The second support assembly 9 includes a second overlapping portion 101 that overlaps the second holder 15 at the second overlapping position R1 when viewed vertically, a second base 102 supporting the second overlapping portion 101, and a second mover 106 that moves the second overlapping portion 101 and the second base 102 in the holding direction X. In other words, in this example, the second mover 106 is shared by both the second restrictor assembly 7 and the second support assembly 9. The second overlapping portion 101 is adjacent to the second base 102 on the first side X1 in the holding direction. In the illustrated example, the second overlapping portion 101 is continuous with the second base 102. The second overlapping portion 101 and the second base 102 are each in the form of a plate elongated in the width direction Y. In this example, the second overlapping portion 101 and the second base 102 are moved integrally by the second mover 106 in the holding direction X. At the second overlapping position R1, the second overlapping portion 101 and the second base 102 protrude inward in the holding direction X (toward the first side X1 in the holding direction) relative to the second cover 17b. At the second non-overlapping position R2, the second overlapping portion 101 and the second base 102 are on the second side X2 relative to the second overlapping position R1 in the holding direction, entirely housed inside the second cover 17b. At the second non-overlapping position R2, the second overlapping portion 101 at a position not overlapping the second holder 15 when viewed vertically may or may not be housed in the second cover 17b. In the example in FIG. 7, the second overlapping portion 101 at the second overlapping position R1 is below the second support 46 and overlaps at least a part of the second support 46 when viewed vertically. More specifically, at the second overlapping position R1, the second overlapping portion 101 overlaps a portion of the second support 46 disposed on the first side X1 in the holding direction relative to the second support plate 46a when viewed vertically, without overlapping the second support plate 46a on which the article W is placed. At the second overlapping position R1, the second overlapping portion 101 may overlap, for example, the entire second support 46 or overlap the second support plate 46a alone when viewed vertically.

In this example, the second mover 106 has the same structure as the first mover 96. The second mover 106 is disposed in the second cover 17b. The second mover 106 includes a link 97 and an advancement-retraction motor (not shown). In the illustrated example, the second base 102 is supported from above by link members 64 included in the link 97. The link 97 transmits a driving force from the advancement-retraction motor to the second base 102. As described above, the second pressing members 71 are supported by the second base 102 with the second supporters 72. The second overlapping portion 101 is continuous with the second base 102, as described above. Thus, the second pressing members 71 and the second overlapping portion 101 move integrally in the holding direction X, or in other words, advance and retract relative to the second cover 17b, as driven by the second mover 106. In the illustrated example, multiple (two in this example) second pressing members 71 are at separate positions in the width direction Y. The restrictor 3 may include a single first pressing member 61 and a single second pressing member 71 or may include different numbers of first pressing members 61 and second pressing members 71.

As shown in FIG. 8, the controller H controls the traveler 11, the holding device 2, the lifter 13, and the restrictor 3. The controller H can communicate with a host controller C that centrally controls the transport facility 10. The controller H and the host controller C each include, for example, a processor such as a microcomputer and peripheral circuitry such as a memory. The functions of the components are implemented by the above hardware and a program executable on a processor such as a computer cooperating with each other.

The control for transferring an article W placed on the transfer area 92 to the transport vehicle 1 will now be described. The controller H causes the traveler 11 to travel to a position corresponding to a predetermined transfer area 92 (a position on the rails 16 set above the article mount 94 in this example) as indicated by a transfer command received from the host controller C. As shown in FIG. 9, the controller H controls the lifter 13 to lower the holding device 2 holding no article W from the housing height V1 to the transfer height V2 (S01). The controller H then controls the holding device 2 to hold the article W with the pair of holders 4 (S02). In this example, the controller H lowers the pair of holders 4 remaining at the holding position T1 from the housing height V1 and switches the position of the pair of holders 4 from the holding position T1 to the releasing position T2 at a predetermined height above the transfer height V2. When the pair of holders 4 in the releasing position T2 are at the transfer height V2, or more specifically, when the first support plate 42a and the second support plate 46a in the pair of holders 4 are below the article W at the transfer height V2, the controller H switches the position of the pair of holders 4 from the releasing position T2 to the holding position T1. Subsequently, the controller H raises the holding device 2 and the article W held by the holding device 2 from the transfer height V2 to the housing height V1 (S03). In response to the holding device 2 and the article W at the housing height V1, or in other words, being housed in the housing 12, the controller H performs a restriction process (S04). In the restriction process, the controller H causes the first restrictor assembly 6 to switch from the first unrestrictive position P2 to the first restrictive position P1, and the second restrictor assembly 7 to switch from the second unrestrictive position Q2 to the second restrictive position Q1. This causes the first holder 14 to be pressed by the first pressing members 61 from the first side X1 in the holding direction.

This also causes the second holder 15 to be pressed by the second pressing members 71 from the second side X2 in the holding direction. In this example, the first pressing members 61 press the first lower end portion 41a of the first extension 41, and the second pressing members 71 press the second lower end portion 45a of the second extension 45. Thus, the lower end portions of the first extension 41 and the second extension 45 that tend to move more outward in the holding direction X are pressed from both outer sides in the holding direction X by the first pressing members 61 and the second pressing members 71. This effectively restricts outward movement of the pair of holders 4 in the holding direction X. This reliably restricts the article W from falling off the pair of holders 4. When lowering the holding device 2 and the article W at the housing height V1 to the transfer height V2, the controller H performs a restriction removing process. In the restriction removing process, with the pair of holders 4 remaining at the holding position T1, the controller H causes the first restrictor assembly 6 to switch from the first restrictive position P1 to the first unrestrictive position P2, and the second restrictor assembly 7 to switch from the second restrictive position Q1 to the second unrestrictive position Q2. The controller H then lowers the holding device 2 and the article W. The first restrictor assembly 6 and the second restrictor assembly 7 may switch their positions at the same time or at different times.

### Other Embodiments

A transport vehicle according to other embodiments will now be described.
(1) In the above embodiment, the lifter 13 raises and lowers the holding device 2 and the article W held by the holding device 2 between the housing height V1 and the transfer height V2 that is lower than the housing height V1, but the structure is not limited to this example. The lifter 13 may raise and lower the holding device 2 and the article W held by the holding device 2 between a housing height V1 and a transfer height V2 that is higher than the housing height V1. The lifter 13 may have such a structure when, for example, the transport vehicle 1 is a trackless transport vehicle on which an article W is placed and transported, such as an automated guided vehicle (AGV) or an autonomous mobile robot (AMR). In some embodiments, the transport vehicle 1 may include no lifter 13. In such a structure without raising and lowering of the holding device 2, the first restrictor assembly 6 may switch from the first unrestrictive position P2 to the first restrictive position P1 and the second restrictor assembly 7 may switch from the second unrestrictive position Q2 to the second restrictive position Q1 in response to the pair of holders 4 switching from the releasing position T2 to the holding position T1. The transport vehicle 1 may be a tracked transport vehicle that travels along fixed rails, other than a trackless transport vehicle.
(2) In the above embodiment, the first restrictor assembly 6 at the first restrictive position P1 presses a portion in the first extension 41 and below the first upper portion 114, and the second restrictor assembly 7 at the second restrictive position Q1 presses a portion in the second extension 45 and below the second upper portion 115, but the structure is not limited to this example. The first restrictor assembly 6 at the first restrictive position P1 may press the first support 42, and the second restrictor assembly 7 at the second restrictive position Q1 may press the second support 46. As described above, the portions to be pressed by the first restrictor assembly 6 and the second restrictor assembly 7 may be changed as appropriate.
(3) In the above embodiment, the restrictor 3 includes the first support assembly 8 and the second support assembly 9, but the structure is not limited to this example. The restrictor 3 may include neither the first support assembly 8 nor the second support assembly 9. In the above embodiment, the first support assembly 8 shares the first mover 96 with the first restrictor assembly 6 to switch the positioning in response to the operation of the first restrictor assembly 6. The second support assembly 9 shares the second mover 106 with the second restrictor assembly 7 to switch the positioning in response to the operation of the second restrictor assembly 7. However, the structure is not limited to this example. The first support assembly 8 may switch its positioning in response to an operation of an assembly different from the first restrictor assembly 6. The second support assembly 9 may switch its positioning in response to an operation of an assembly different from the second restrictor assembly 7.
(4) In the above embodiment, the first restrictor assembly 6 and the second restrictor assembly 7 are disposed in the cover 17 in the housing 12, but the structure is not limited to this example. The first restrictor assembly 6 and the second restrictor assembly 7 may each be disposed in a part other than the housing 12, such as the traveler 11.
(5) The structure described in each of the above embodiments may be combined with any other structures described in the other embodiments unless any contradiction arises. For other structures as well, the embodiments described herein are merely illustrative in all aspects and may be modified as appropriate without departing from the spirit and scope of the disclosure.

### Overview of Embodiments

An overview of the transport vehicle described above is provided below.

A transport vehicle according to an aspect of the disclosure is a transport vehicle for transporting an article. The transport vehicle includes a holding device that holds and releases the article, and a restrictor that restricts the article held by the holding device from falling. The holding device includes a pair of holders that hold the article, and a holder drive that switches the pair of holders between a holding position at which the pair of holders are closer to each other to hold the article and a releasing position at which the pair of holders are away from each other to release the article. The pair of holders include a first holder on a first side in a holding direction in which the pair of holders move closer to and away from each other, and a second holder on a second side in the holding direction. The second side is opposite to the first side. The first holder includes a first extension disposed on the first side relative to the article in the holding direction and extending vertically, and a first support protruding from the first extension toward the second side in the holding direction to support a bottom of the article from below. The second holder includes a second extension disposed on the second side relative to the article in the holding direction and extending vertically, and a second support protruding from the second extension toward the first side in the holding direction to support the bottom of the article from below. The restrictor includes a first restrictor assembly and a second restrictor assembly. The first restrictor assembly is switchable between a first restrictive position and a first unrestrictive position. The first restrictive position is a position to restrict movement of the first holder toward the first side in the holding direction with the first holder and the second holder at the holding position. The first unrestrictive position is a position to remove restriction on the first holder. The second restrictor assembly is switchable between a second restrictive position and a second unrestrictive position. The second restrictive position is a position to restrict movement of the second holder toward the second side in the holding direction with the first holder and the second holder at the holding position. The second unrestrictive position is a position to remove restriction on the second holder.

This structure includes the first restrictor assembly that restricts movement of the first holder toward the first side in the holding direction and the second restrictor assembly that restricts movement of the second holder toward the second side in the holding direction. The structure can thus restrict the distance between the first support and the second support from increasing in the holding direction due to, for example, warping or rattling of the holders, thus restricting the article from falling off the pair of holders.

The structure restricts movement of each of the pair of holders with the first restrictor assembly at the first restrictive position and the second restrictor assembly at the second restrictive position, thus easily reducing vibrations of the article being transported by the transport vehicle.

The structure also allows the pair of holders to easily move in the holding direction and switch between the holding position and the releasing position by switching the first restrictor assembly to the first unrestrictive position and the second restrictor assembly to the second unrestrictive position. Thus, the pair of holders can appropriately hold and release the article.

As described above, the structure can appropriately hold the article during transportation.

The holder drive may be disposed above the article held by the pair of holders and apply a driving force to a first upper portion being a portion in the first extension and above the article and to a second upper portion being a portion in the second extension and above the article. The first restrictor assembly at the first restrictive position may press a portion in the first extension and below the first upper portion or press the first support. The second restrictor assembly at the second restrictive position may press a portion in the second extension and below the second upper portion or press the second support.

In the above structure in which the holder drive applies a driving force to the portions in the first extension and the second extension and above the article, the first extension and the second extension tend to be elongated vertically. Thus, warping or rattling of the holders can easily increase the distance between the first support and the second support in the holding direction. However, in the above structure, the first restrictor assembly presses the portion in the first holder and below the first upper portion, and the second restrictor assembly presses the portion in the second holder and below the second upper portion, thus appropriately restricting outward movement (movement away from each other) of the pair of holders in the holding direction. This can reliably restrict the article from falling off the pair of holders.

The restrictor may further include a first support assembly and a second support assembly. In response to the first restrictor assembly at the first restrictive position, the first support assembly may be at a first overlapping position below the first holder at which the first support assembly overlaps the first holder when viewed vertically. In response to the first restrictor assembly at the first unrestrictive position, the first support assembly may be at a first non-overlapping position at which the first support assembly avoids overlapping the first holder when viewed vertically. In response to the second restrictor assembly at the second restrictive position, the second support assembly may be at a second overlapping position below the second holder at which the second support assembly overlaps the second holder when viewed vertically. In response to the second restrictor assembly at the second unrestrictive position, the second support assembly may be at a second non-overlapping position at which the second support assembly avoids overlapping the second holder when viewed vertically.

In this structure, the support assemblies (the first support assembly and the second support assembly) can support, for example, any holder or holding device falling off the transport vehicle from below. Thus, the article is less likely to fall off the transport vehicle in such cases.

In this structure, the first support assembly is at the first non-overlapping position in response to the first restrictor assembly at the first unrestrictive position, and the second support assembly is at the second non-overlapping position in response to the second restrictor assembly at the second unrestrictive position. The first support assembly and the second support assembly can thus easily avoid interfering with the article or the holding device when, for example, the holding device is raised or lowered.

The transport vehicle may further include a traveler that travels, a housing supported by the traveler to house the holding device and the article held by the holding device during travel of the traveler, and a lifter that raises and lowers the holding device to place the holding device into and out of the housing. The first restrictor assembly and the second restrictor assembly may be disposed in the housing.

This structure can transfer the article to and from the transfer area below or above the transfer vehicle by raising and lowering the holding device. The structure can also restrict outward movement of the pair of holders in the holding direction with the first restrictor assembly and the second restrictor assembly when the holding device and the article are housed in the housing. Thus, the article housed in the housing can appropriately avoid falling off the pair of holders.

The transport vehicle according to one or more embodiments of the disclosure produces at least one of the effects described above.

What is claimed is:

1. A transport vehicle for transporting an article, the transport vehicle comprising:
a holding device configured to hold and release the article; and
a restrictor configured to restrict the article held by the holding device from falling, and
wherein:
the holding device comprises:
a pair of holders configured to hold the article, and
a holder drive configured to switch the pair of holders between a holding position at which the pair of holders are closer to each other to hold the article and a releasing position at which the pair of holders are away from each other to release the article,
the pair of holders comprises:
a first holder on a first side in a holding direction in which the pair of holders move closer to and away from each other, and
a second holder on a second side in the holding direction, the second side located opposite to the first side,
the first holder comprises:
a first extension disposed on the first side relative to the article in the holding direction and extending vertically, and
a first support protruding from the first extension toward the second side in the holding direction to support a bottom of the article from below,
the second holder comprises:
a second extension disposed on the second side relative to the article in the holding direction and extending vertically, and
a second support protruding from the second extension toward the first side in the holding direction to support the bottom of the article from below,
the restrictor comprises a first restrictor assembly and a second restrictor assembly,
the first restrictor assembly is switchable between a first restrictive position and a first unrestrictive position, the first restrictive position is a position to restrict movement of the first holder toward the first side in the holding direction with the first holder and the second holder at the holding position, and the first unrestrictive position is a position to remove restriction on the first holder, and
the second restrictor assembly is switchable between a second restrictive position and a second unrestrictive position, the second restrictive position is a position to restrict movement of the second holder toward the second side in the holding direction with the first holder and the second holder at the holding position, and the second unrestrictive position is a position to remove restriction on the second holder.

2. The transport vehicle according to claim 1, wherein:
the holder drive is disposed above the article held by the pair of holders and applies a driving force to a first upper portion that is a portion in the first extension and above the article and to a second upper portion that is a portion in the second extension and above the article,
the first restrictor assembly at the first restrictive position presses a portion in the first extension and below the first upper portion or presses the first support, and
the second restrictor assembly at the second restrictive position presses a portion in the second extension and below the second upper portion or presses the second support.

3. The transport vehicle according to claim 1, wherein:
the restrictor further comprises a first support assembly and a second support assembly,
in response to the first restrictor assembly at the first restrictive position, the first support assembly is at a first overlapping position below the first holder at which the first support assembly overlaps the first holder when viewed vertically,
in response to the first restrictor assembly at the first unrestrictive position, the first support assembly is at a first non-overlapping position at which the first support assembly avoids overlapping the first holder when viewed vertically,
in response to the second restrictor assembly at the second restrictive position, the second support assembly is at a second overlapping position below the second holder at which the second support assembly overlaps the second holder when viewed vertically, and
in response to the second restrictor assembly at the second unrestrictive position, the second support assembly is at a second non-overlapping position at which the second support assembly avoids overlapping the second holder when viewed vertically.

4. The transport vehicle according to claim 1, further comprising:
a traveler configured to travel;
a housing supported by the traveler and configured to house the holding device and the article held by the holding device during travel of the traveler; and
a lifter configured to raise and lower the holding device to place the holding device into and out of the housing, and
wherein the first restrictor assembly and the second restrictor assembly are disposed in the housing.
